(19) United States
(12) Patent Application Publication
(10) Pub. No.: US 2006/0186462 A1
(43) Pub. Date: Aug. 24, 2006

(54) Nonvolatile memory device and method of fabricating the same

(75) Inventors: Jeong-Hee Han, Suwon-si (KR); Ju-Hyung Kim, Yongin-si (KR); Chung-Woo Kim, Suwon-si (KR); Sang-Hun Jeon, Seoul (KR); Youn-Seok Jeong, Seoul (KR); Seung-Hyun Lee, Metropolitan City (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/357,329

(22) Filed: Feb. 21, 2006

(30) Foreign Application Priority Data
Feb. 21, 2005 (KR) 10-2005-0014087

(51) Int. Cl. H01L 29/788

(52) U.S. Cl. 257/315

(57) ABSTRACT

Provided are example embodiments of fabrication methods and resulting structures suitable for use in nonvolatile memory devices formed on semiconductor substrates. The example embodiments of the gate structures include a first insulating film formed on the semiconductor substrate, a storage node formed on the first insulating film for storing charges, a second insulating film formed on the storage node, a third insulating film formed on the second insulating film, and a gate electrode formed on the third insulating film. The insulating films are selected whereby the dielectric constant of one or both of the second and third insulating films is greater than the dielectric constant of the first insulating film.

### PRIORITY STATEMENT

This application claims the benefit of Korean Patent Application No. 10-2005-0014087, filed on Feb. 21, 2005, in the Korean Intellectual Property Office, the disclosure of which is incorporated herein, in its entirety, by reference.

### BACKGROUND OF THE INVENTION

1. Field of the Invention

The invention relates to nonvolatile memory devices and methods of fabricating such devices and, more particularly, to nonvolatile memory devices that incorporate a charge storage node and methods of fabricating the such charge storage nodes.

2. Description of the Related Art

In order to write or erase data, nonvolatile memory devices may use a threshold voltage transition of a transistor, a charge displacement and/or a resistance change. Those memory devices that use a threshold voltage transition for writing or erasing data may be referred to as charge storing memory devices due to the presence of a storage node used for storing an electrical charge. For example, embodiments of charge storing memory devices include both floating gate memory devices that use a floating gate as a storage node and silicon-oxide-nitride-oxide-silicon (SONOS) memory devices that use a charge trapping layer as a storage node.

FIG. 1 illustrates a cross-sectional view of a charge storing nonvolatile memory device 100 that incorporates a conventional SONOS construction that uses a nitride film 120 as a charge trapping layer in the storage node. A tunnel insulating film, for example, an oxide film 115, for tunneling charge or injecting hot carriers is provided between the nitride film 120 and a semiconductor substrate 105. A blocking insulating film, for example, an oxide film 125, is provided between the nitride film 120 and a control gate electrode 130. In a conventional SONOS construction, the semiconductor substrate 105 will be silicon and the control gate electrode 130 will be polysilicon, although those skilled in the art will appreciate that other semiconductor and conductive materials may be used in fabricating similar structures.

A writing operation may be performed on memory device 100 by applying a positive voltage to the control gate electrode 130. In response to the positive voltage on the control gate 130, electrons accelerated from the source/drain regions 110 can be injected into the nitride film 120, or electrons of the semiconductor substrate 105 can be injected into the nitride film 120 by tunneling. Conversely, an erasing operation may be performed on memory device 100 by applying a negative voltage to the control gate electrode 130 or by applying a positive voltage to the semiconductor substrate 105 whereby electrons stored in the nitride film 120 are erased by tunneling into the semiconductor substrate 105.

FIG. 2 illustrates energy bands 105a, 115a, 120a, 125a, and 130a respectively corresponding to the semiconductor substrate 105, the oxide film 115, the nitride film 120, the oxide film 125, and the control gate electrode 130. As illustrated in FIGS. 1 and 2, when the voltage applied to the control gate electrode 130 in the erasing operation increases, the bending of the energy bands 115a and 125a corresponding to the oxide films 115 and 125 increases. Establishing such a condition in memory device 100 allows both the tunneling of electrons from the nitride film 120 into the semiconductor substrate 105 through oxide film 115 and the back tunneling of free electrons present in the control gate electrode 130 into the nitride film 120 through the oxide film 125.

FIG. 3 is a graph illustrating a time variation of a threshold voltage with respect to an erasing voltage applied to a memory device 100 having a construction as illustrated in FIG. 1. As illustrated in FIG. 3, as the absolute value of the erasing voltage increases, the threshold voltage is reduced while the saturation threshold voltage increases. This result reflects the condition whereby as the absolute value of the erasing voltage increases, the back tunneling also increases, thereby reducing the efficiency of the erasing operation.

Referring again to FIG. 1, for example, the effects associated with an increasing absolute value of the erasing voltage can be suppressed by reducing the thickness of the oxide film 115, through which the tunneling occurs, relative to the thickness of the oxide film 125, through which the back tunneling occurs. However, as the thickness of the oxide film 115 is reduced, there is an increased likelihood that tunneling will occur through the oxide film 115 even in the absence of an erasing voltage applied to the control gate electrode 130. Such controlled tunneling will tend to degrade or impair the retention characteristics of the memory device 100.

FIG. 4 is a graph illustrating a relationship between variations in the threshold voltage in a retention state and the threshold voltage in an erasing state for memory devices 100. As illustrated in FIG. 4, the saturation threshold voltage Vₜₕ in the erasing state and the retention characteristics of the associated memory device are inversely proportional to each other. Accordingly, efforts to improve the erasing efficiency of such memory devices tend to result in degraded or compromised retention characteristics.

### SUMMARY OF THE INVENTION

Example embodiments of the invention provide nonvolatile memory devices that exhibit improved erasing efficiency while also maintaining or improving retention characteristics.

Example embodiments of the invention provide methods of fabricating nonvolatile memory devices including a gate structure formed on a semiconductor substrate in which the gate structure includes a first insulating film formed on the semiconductor substrate; a storage node formed on the first insulating film for storing charges; a second insulating film formed on the storage node; a third insulating film formed on the second insulating film; and a gate electrode formed on the third insulating film, wherein the dielectric constant of at least one of the second and third insulating films is greater than that of the first insulating film.

Example embodiments of the invention provide methods of fabricating nonvolatile memory devices including a gate structure formed on a semiconductor substrate in which the gate structure in which the energy band gap at least one of the second insulating film and the third insulating film is greater than the energy band gap of the storage node.

Example embodiments of the invention also provide methods of fabricating nonvolatile memory devices on a semiconductor substrate that include forming spaced apart source and drain regions in the semiconductor substrate; forming a first insulating film on the semiconductor substrate between the source and the drain; forming a storage node on the first insulating film for storing charges; forming a second insulating film on the storage node, for example an oxide film; forming a third insulating film on the second insulating film, for example a nitride film; and forming a control gate electrode on the third insulating film.

Example embodiments of the invention also provide methods of fabricating nonvolatile memory devices on a semiconductor substrate that include forming a first insulating layer on the semiconductor substrate; forming a storage node layer on the first insulating layer; forming a second insulating layer on the storage node layer; forming a third insulating layer on the second insulating layer; forming a control gate electrode layer on the third insulating layer; forming a photoresist pattern that exposes a predetermined portion of the control gate electrode layer on the control gate electrode layer; and forming a gate structure by etching the control gate electrode layer, the third insulating layer, the second insulating layer, the storage node layer, and the first insulating layer using the photoresist pattern as an etching protection mask.

### BRIEF DESCRIPTION OF THE DRAWINGS

The example embodiments of the invention will be readily understood through reference to the following detailed description and the accompanying drawings, in which identical reference numerals have been used to designate identical and/or corresponding elements and in which:

FIG. 1 is a cross-sectional view of a conventional SONOS type memory device;

FIG. 2 is a schematic diagram illustrating energy bands corresponding to the conventional SONOS type memory device corresponding to FIG. 1;

FIG. 3 is a graph illustrating a time variation of threshold voltage with respect to an erasing voltage applied to conventional SONOS type memory devices corresponding to FIG. 1;

FIG. 4 is a graph illustrating a relationship between variations in the threshold voltage in a retention state and the threshold voltage in an erasing state of conventional SONOS type memory devices corresponding to FIG. 1;

FIG. 5 is a cross-sectional view illustrating a nonvolatile memory device according to an example embodiment of the invention;

FIG. 6 is a schematic diagram illustrating energy bands corresponding to nonvolatile memory devices having a construction corresponding to FIG. 5;

FIG. 7 is a graph illustrating a relationship between a threshold voltage in a retention state and a flat band voltage in an erasing state for both conventional SONOS type memory devices corresponding to FIG. 1 and the nonvolatile memory devices corresponding to FIG. 5; and

FIGS. 8-10 are cross-sectional views illustrating certain steps performed and intermediate structures fabricated during a method of fabricating a nonvolatile memory device according to an example embodiment of the invention.

These drawings are provided for illustrative purposes only and are not drawn to scale. The spatial relationships and relative sizing of the elements illustrated in the various embodiments, for example, the various films comprising the gate structures, may have been reduced, expanded or rearranged to improve the clarity of the figure with respect to the corresponding description. The figures, therefore, should not be interpreted as accurately reflecting the relative sizing, value or positioning of the corresponding structural elements that could be encompassed by actual nonvolatile memory devices manufactured according to the example embodiments of the invention.

### DETAILED DESCRIPTION OF EXAMPLE EMBODIMENTS

The invention will now be described more fully with reference to the accompanying drawings in which example embodiments of the invention are shown. As will be appreciated by those skilled in the art, however, the invention may be embodied in many different forms and should not, therefore, be construed as being limited to the example embodiments. Indeed, these example embodiments are provided to ensure that this disclosure will be thorough and complete, and will fully convey the concept of the invention to those skilled in the art.

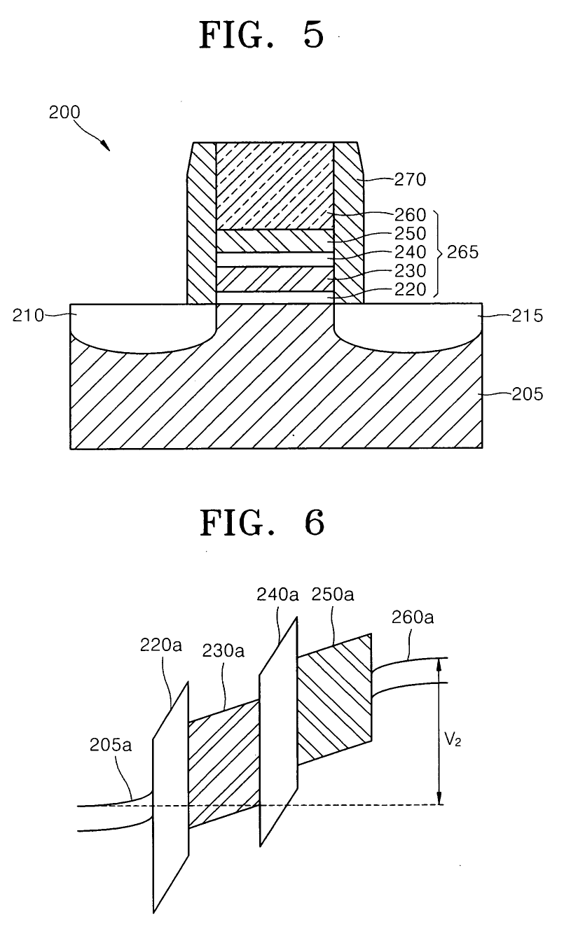

FIG. 5 is a cross-sectional view illustrating a nonvolatile memory device 200 according to an example embodiment of the invention. As illustrated in FIG. 5, the nonvolatile memory device 200 includes a gate structure 265 formed on a semiconductor substrate 205 between a source 210 and a drain 215. The gate structure 265 includes a storage node 230 for storing charges and a gate electrode 260 for controlling the operation of the storage node 230. As illustrated in FIG. 5, the gate structure 265 may also include spacer insulating films 270, also simply referred to as spacers, formed on the side surfaces of the gate structure 265.

The gate structure 265 includes a first insulating film 220, the storage node 230, a second insulating film 240, a third insulating film 250, and the control gate electrode 260. During fabrication of the gate structure 265, the first insulating film 220 is formed on the semiconductor substrate 205, and the storage node 230 is formed on the first insulating film 220. The second insulating film 240, the third insulating film 250, and the control gate electrode 260 are then sequentially formed on the storage node 230.

A writing operation may be performed on the nonvolatile memory device 200 during which electrons are added to the storage node 230 by applying a writing voltage, for example, a positive voltage, to the control gate electrode 260. Conversely, an erasing operation may be performed on the nonvolatile memory device 200 by removing stored electrons from the storage node layer 230 to the semiconductor substrate 205 by applying an erasing voltage, for example, a negative voltage, to the control gate electrode 260.

Depending on the particular structure and materials used to fabricate the nonvolatile memory device 200, the storage node 230 can be configured as a floating gate or a charge trapping layer. For example, the storage node 230 may be formed from a variety of a materials capable of storing or trapping a sufficient quantity of electrons by utilizing electron traps, chemical bonding, quantum or energy wells, nanocrystals, nanoclusters or nanodots. A satisfactory storage node 230 can, for example, be fabricated from silicon nitride, polysilicon, nanocrystals, nanoclusters or nanodots.

As used herein, nanocrystals, nanoclusters and nanodots refer to “nanostructures” that typically comprise a semiconductor or dielectric material that includes a characteristic dimension of less than about 500 nm. Typically, this characteristic dimension will be found along the smallest axis of the structure. Nanostructures can be characterized as, for example, substantially crystalline, substantially monocrystalline, polycrystalline, amorphous, or a combination thereof.

The terms “crystalline” or “substantially crystalline,” when used herein with respect to nanostructures reflect the fact that the nanostructures typically exhibit long-range ordering across one or more dimensions. In some instances, nanostructures can include an oxide or other coating and can comprise a core and at least one shell layer. In such instances it will be appreciated that the shell(s) or other coating(s) need not exhibit such ordering and the terms “crystalline,” “substantially crystalline,” “substantially monocrystalline,” or “monocrystalline” are intended to reflect the microstructure of the core material only.

The terms “crystalline” or “substantially crystalline” as used herein are intended to encompass structures that exhibit various defects including, for example, stacking faults, atomic substitutions, and the like, as long as the crystalline structure exhibits long range ordering. The term “monocrystalline” as used herein with respect to a nanostructure indicates that the nanostructure is both substantially crystalline and comprises substantially a single crystal. When used with respect to a nanostructure comprising a core and one or more layers or shells, “monocrystalline” indicates that the core material is substantially crystalline and comprises substantially a single crystal, e.g., a nanocrystal.

The first insulating film 220 is formed from an insulating material through which hot carriers can be injected or electrons can be tunneled into the storage node 230. The first insulating film 220 may, for example, be formed of silicon oxide film. When the first insulating film 220 is formed from silicon oxide, the silicon oxide film will typically have a thickness in a range of 20 to 60 Å. This is because if the first insulating film 220 is a silicon oxide film of less than 20 Å, the tunneling of charges through the first insulating film 220 may occur even without a control voltage being applied to the control gate electrode 260. Conversely, if the first insulating film 220 is a silicon oxide film of more than 60 Å, the control voltages required to induce the desired tunneling of the charges increase and correspondingly reduce the efficiency of the nonvolatile memory device 200.

The second insulating film 240 and the third insulating film 250 are provided for suppressing the reverse tunneling of charges from the control gate electrode 260 to the storage node 230 while the erasing operation is being performed on the nonvolatile memory device 200. In addition, the second insulating film 240 separates the third insulating film 250 from the storage node 230 and provides additional control of the coupling voltage ratio between the control gate electrode 260 and the storage node 230.

The second insulating film 240 and the third insulating film 250 will now be described more in detail with reference to energy bands diagram depicted in FIG. 6 with respect to the nonvolatile memory device 200. As illustrated in FIGS. 5 and 6, the equilibrium state of energy bands 205a, 220a, 230a, 240a, and 250a correspond to the semiconductor substrate 205, the first insulating film 220, the storage node 230, the second insulating film 240, the third insulating film 250 and the control gate electrode 260 of the nonvolatile memory device 200 respectively. As illustrated by the energy bands 205a, 220a, 230a, 240a, and 250a, of FIG. 6, when an erasing voltage is applied to the control gate electrode 260, the energy band 240a of the second insulating film 240 is shifted, but the reverse tunneling from the control gate electrode 260 into the storage node 230 is suppressed by the intervening third insulating film 250.

However, as will be appreciated by those skilled in the art, the presence of the third insulating film 250 will alter the capacitance between the control gate electrode 260 and the semiconductor substrate 205. Accordingly, the magnitude of an electrical field between the storage node 230 and the semiconductor substrate 205 will also be altered. These alterations in both the capacitance and the electrical field resulting from the addition of the third insulating film 250 will tend to change one or more operational characteristics, for example the writing operation, the erasing operation, and/or the operating efficiency of the nonvolatile memory device 200.

Accordingly, the corresponding energy band gaps, dielectric constants, and thicknesses of the second insulating film 240 and the third insulating film 250 should be selected with consideration of both the degree to which reverse tunneling will be suppressed and the degree to which the capacitance will be altered as a result of the additional layer. More specifically, the dielectric constant of at least one of the second and third insulating films 240, 250 may be greater than the dielectric constant of the first insulating film 220.

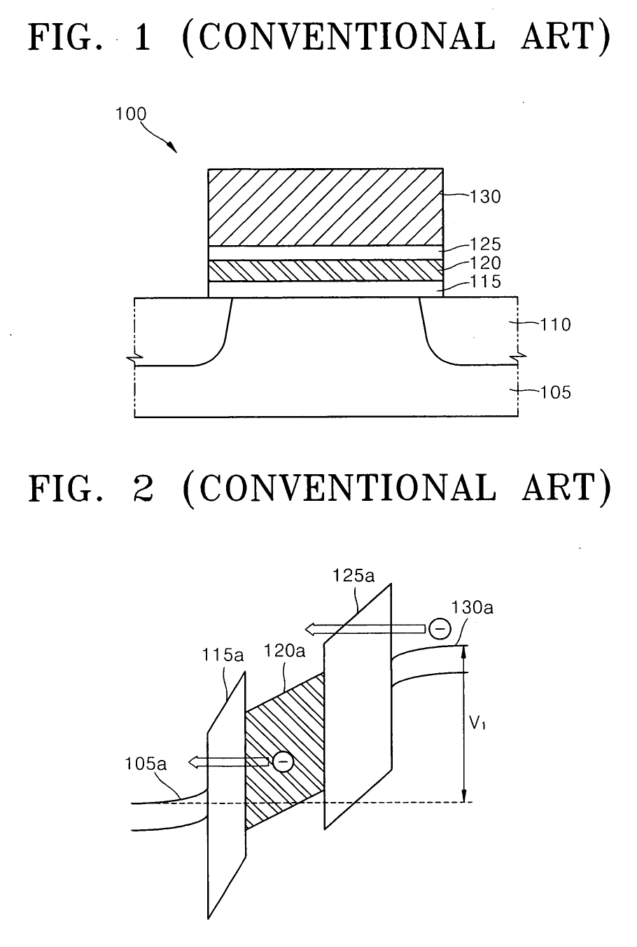

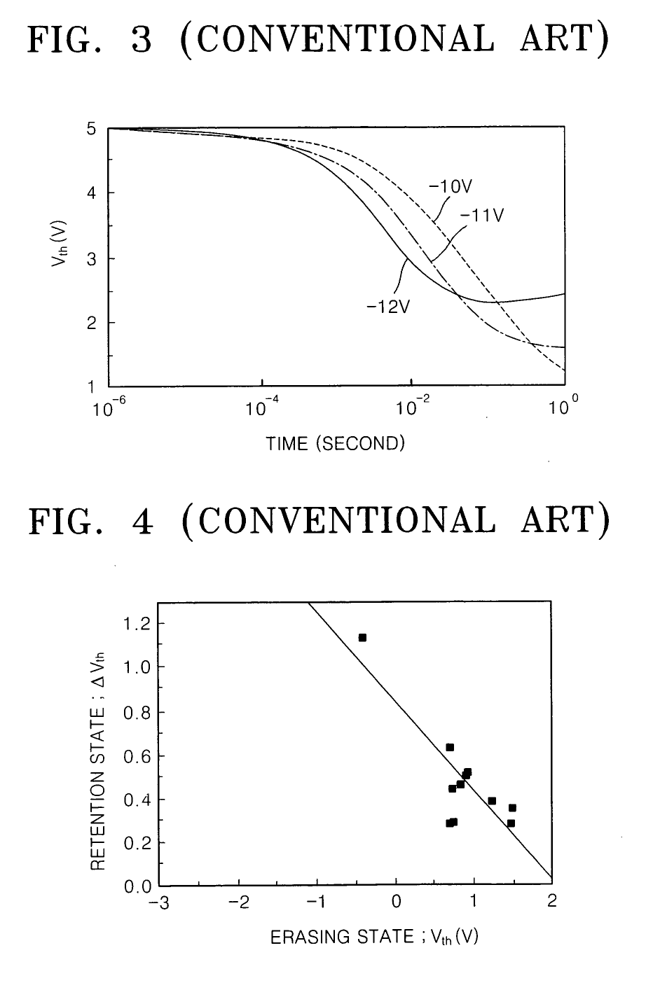

By selecting a material for the second and/or third insulating film that has a higher dielectric constant that than of the first insulating film, the magnitude of the resulting change in capacitance change between the control gate electrode 260 and the semiconductor substrate 205 resulting from the change in physical thickness associated with the second and third insulating films 240 and 250 can be at least partially compensated. Also, a potential V₂ between the semiconductor substrate 205 and the control gate electrode 260 of a nonvolatile memory device 200 can be maintained at a magnitude similar to that of the potential V₁ (see FIG. 2) between the semiconductor substrate 105 and the control gate electrode 130 (see FIG. 1) of a conventional a nonvolatile memory device 100. That is, an effective or electrical oxide thickness (EOT) exhibited between the control gate electrode 260 and the semiconductor substrate 205 can also be maintained at a level corresponding to the EOT exhibited by a conventional device (see FIG. 1) that does not include a third insulating film.

The reverse tunneling of the charges from the storage node 230 into the control gate electrode 260 may be further suppressed by selecting one or more dielectric materials whereby the energy band gap of the second insulating film 240 and/or the third insulating film 250 are greater than the energy band gap of the storage node 230. For example, the second insulating film 240 may be a silicon nitride film and the first and third insulating films 220, 250 may be silicon oxide films. Accordingly, the erasing characteristics of the nonvolatile memory device 200 can be improved by a combination of conventional oxide and nitride insulating films and thereby avoid the need to use one or more exotic, demanding and/or expensive high dielectric constant insulating films.

For example, an acceptable combination of electric field distribution and back tunneling suppression characteristics may be achieved and/or maintained by, decreasing the thickness of the silicon oxide film 240 to compensate for an increased thickness of the silicon nitride film 250. For example, the silicon nitride film 250 may have a thickness of 40 to 100 Å, the silicon oxide film 240 may have a thickness of 20 to 60 Å and the combined thickness of the insulating films 240, 250 may be, for example, 100 to 120 Å.

Also, as noted above, the silicon oxide film 220 will typically have a thickness of at least 20 Å in order to suppress the natural tunneling of the charges during the retention state (during which the memory device is not being written or erased) of the nonvolatile memory device 200. The silicon oxide film 220 will, however, typically not have a thickness of more than 60 Å in order to provide for an acceptable degree of tunneling efficiency during a recording operation.

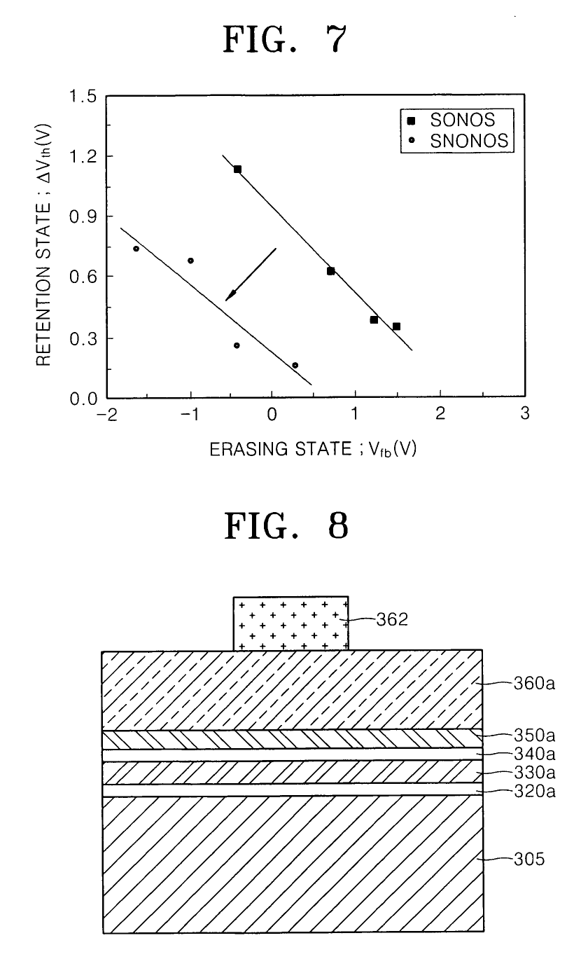

FIG. 7 is a graph showing the relationship between the variation of a threshold voltage ΔVₜₕ in a retention state and a flat band voltage V_{fb} in an erasing state of the conventional memory device 100 of FIG. 1 (squares) and a nonvolatile memory device 200 corresponding to FIG. 5 (circles). In the drawings, the conventional memory device is denoted as a SONOS type memory device and the memory device according to the example embodiment is denoted as a SNONOS type memory device.

As illustrated in FIG. 7, the SNONOS type memory device 200 corresponding to the example embodiment illustrated in FIG. 5 exhibits improved erasing efficiency and retention characteristics relative to the conventional SONOS type memory device 100 (see FIG. 1). In particular, the SNONOS type memory device 200 exhibits both improved retention characteristics at the same erasing efficiency and an improved erasing efficiency for the same retention characteristics. FIG. 7 illustrates that lower flat band voltages, V_{fb}, correspond to higher erasing efficiencies and that lower levels of variation in the threshold voltage, ΔVₜₕ, correspond to higher retention characteristics. Accordingly, when a nonvolatile memory device 200 corresponding according to the example embodiments is used, both the erasing efficiency and the retention characteristics can be improved relative to a conventional memory device 100 while maintaining a similar writing speed.

FIGS. 8 through 10 are cross-sectional views illustrating steps in an example embodiment of a method of fabricating a nonvolatile memory device according to the invention. Because the elements of the nonvolatile memory device illustrated in FIG. 8 are substantially identical to the elements incorporated in the memory device 200 illustrated in FIG. 5, the descriptions will not be repeated. In FIGS. 5 and 8-10, reference numerals in which the last two digits are identical, e.g., 205 and 305, denote corresponding materials, elements and/or structures.

As illustrated in FIG. 8, a first insulating layer 320a, a storage node layer 330a, a second insulating layer 340a, a third insulating layer 350a, and a control gate electrode layer 360a are sequentially formed on a semiconductor substrate 305. The first insulating layer 320a can be a silicon oxide film that may be formed using a chemical vapor deposition (CVD) method or by oxidizing a surface portion of the semiconductor substrate 305.

The storage node layer 330a can be formed of silicon nitride, polysilicon, nanocrystal, nanocluster or nanodot materials. If the storage node layer 330a is formed from silicon nitride, the silicon nitride film may be formed using a LPCVD method using a mixture of dichlorosilane (DCS) and NH₃ gases. The mixing ratio of the NH₃ to DCS gases may be maintained in a range of 1.5 to 2.5 to provide a degree of control over the resulting dielectric constant and trap density. Accordingly, the trap density of the storage node layer 330a may be greater than that exhibited by a stoichiometric Si₃N₄ film.

The second insulating film 340a can be a silicon oxide film formed using an LPCVD method and the third insulating film 350a may be a silicon nitride film formed using another LPCVD method using a mixture of DCS and NH₃ gases. As with the formation of the storage node layer 330a, the mixing ratio of the NH₃ to DCS gases may be maintained in a range of 0.65 to 1.0 to produce a third insulating film 350a of silicon nitride that exhibits a trap density that is lower than that of the storage node layer 330a.

In the example embodiment, as described above, the second insulating layer 340a and the third insulating layer 350a, respectively, can be formed from silicon oxide and silicon nitride. Accordingly, the second insulating layer 340a and the third insulating layer 350a can be fabricated using conventional techniques and equipment and thereby avoid the need for the new equipment and/or technology required to produce more exotic high-K materials. Accordingly, fabricating nonvolatile memory devices according to the example embodiment will be economical since it does not require new equipment or technology. Furthermore, the long history of silicon oxide and silicon nitride films ensure that these are proven materials that will not react with each other or contaminate a process line.

The control gate electrode layer 360a can then be formed on the third insulating layer 350a by depositing a layer of polysilicon. Accordingly, the nonvolatile memory device may incorporate a conventional polysilicon gate structure and avoid the need to form a metal gate electrode structure.

Next, a photoresist pattern 362 is formed to expose predetermined regions of the control gate electrode layer 360a while protecting other regions. The photoresist pattern 362 can be formed using conventional photolithography techniques well known in the art to achieve the necessary pattern dimensions and provide sufficient resistance to the subsequent etch process.

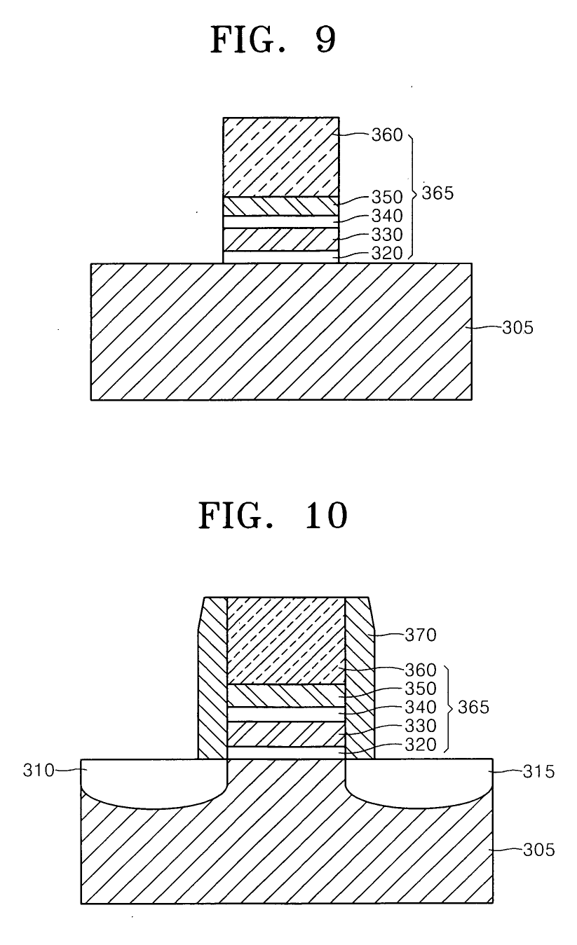

As illustrated in FIG. 9, a gate structure 365 may then be formed by etching the unprotected regions of control gate electrode layer 360a, the third insulating layer 350a, the second insulating layer 340a, the storage node layer 330a, and the first insulating layer 320a using the photoresist pattern 362 as an etching protection mask. The resulting gate structure 365 will include a first insulating film 320, a storage node layer 330, a second insulating film 340, a third insulating film 350, and a control gate electrode 360.

As illustrated in FIG. 10, insulting spacers 370 may then be formed on side walls of the gate structure 365 using a conventional deposition and etchback process. In some instances, a CMP process may also be utilized to provide additional control of the resulting structure and/or surface profile. Next, source 310 and drain 315 regions may be formed by doping portions of the semiconductor substrate 305 with one or more impurity species. The gate structure 365 may be used as an implant mask to provide self-aligned source and drain regions in the semiconductor substrate 305 adjacent opposite sides of the gate structure 365. Electrical connections (not shown) may subsequently be formed to the source and drain regions 310, 315 and the control gate 360 using conventional wiring processes and conductive materials that are well known to those skilled in the art.

The invention has been disclosed with reference to certain example embodiments as detailed above in this specification and as illustrated in the accompanying drawings. These disclosures are provided for illustrative purposes only and are not intended to limit, and should not be deemed to limit, the scope of the invention unduly. Persons skilled in the art will understand and appreciate that various changes, modifications and combinations of the example embodiments detailed above, and/or the materials and elements of the example embodiments, may be made without departing from the spirit of the invention.

What is claimed is:

1. A nonvolatile memory device having a gate structure formed on a substrate, the gate structure comprising:
a first insulating film having a first dielectric constant κ₁ and an energy band gap D_{bg1} formed on the semiconductor substrate;
a storage node film having a band gap S_{bg} formed on the first insulating film;
a second insulating film having a second dielectric constant κ₂ and an energy band gap D_{bg2} formed on the storage node film;
a third insulating film having a third dielectric constant κ₃ and an energy band gap D_{bg3} formed on the second insulating film; and
a gate electrode formed on the third insulating film,
wherein at least one of the expressions κ₂>κ₁ and κ₃>κ₁ is satisfied.

2. The nonvolatile memory device according to claim 1, wherein:
at least one of the expressions D_{bg2}>S_{bg} and D_{bg3}>S_{bg} is satisfied.

3. The nonvolatile memory device according to claim 1, wherein:
the expression κ₃>κ₁ is satisfied.

4. The nonvolatile memory device according to claim 3, wherein:
the third insulating film is a silicon nitride film.

5. The nonvolatile memory device according to claim 4, wherein:
the third insulating film has a thickness T₃ in a range of 40 to 100 Å.

6. The nonvolatile memory device according to claim 4, wherein:
the second insulating film is a silicon oxide film.

7. The nonvolatile memory device according to claim 6, wherein:
the second insulating film has a thickness T₂ in a range of 20 to 60 Å.

8. The nonvolatile memory device according to claim 1, wherein:
the first insulating film is a silicon oxide film.

9. The nonvolatile memory device according to claim 8, wherein:
the first insulating film has a thickness T₁ in a range of 20 to 60 Å.

10. The nonvolatile memory device according to claim 1, wherein:
the storage node film is formed from a material selected from a group consisting of silicon nitride, polysilicon, nanocrystal, nanoclusters and nanodots.

11. A nonvolatile memory device comprising:
a semiconductor substrate;
a gate structure having sidewalls formed on the semiconductor substrate, the gate structure including a first insulating pattern formed on the semiconductor substrate, a storage node pattern formed on the first insulating pattern; a second insulating pattern formed on the storage node layer, a third insulating pattern formed on the second insulating pattern, and a control gate electrode formed on the third insulating pattern; and
source and drain regions formed in the semiconductor substrate adjacent the sidewalls of the gate structure.

12. The nonvolatile memory device according to claim 11, wherein:
the third insulating pattern is formed from a silicon nitride film.

13. The nonvolatile memory device according to claim 12, wherein:
the second insulating pattern is formed from a silicon oxide film.

14. The nonvolatile memory device according to claim 13, wherein:
the silicon oxide film has a thickness in a range of 20 to 60 Å and the silicon nitride film has a thickness in a range of 40 to 100 Å.

15. The nonvolatile memory device according to claim 11, wherein:
the storage node pattern is formed from at least one material selected from a group consisting of silicon nitride, polysilicon, nanocrystals, nanoclusters and nanodots.

16. A method of fabricating a nonvolatile memory device, comprising:
forming a first insulating layer on a semiconductor substrate;
forming a storage node layer on the first insulating layer;
forming a second insulating layer on the storage node layer;
forming a third insulating film on the second insulating layer;
forming a control gate electrode layer on the third insulating layer;
forming a photoresist pattern that exposes predetermined portions of a surface of the control gate electrode layer; and
forming a gate structure by etching the control gate electrode layer, the third insulating layer, the second insulating layer, the storage node layer, and the first insulating layer using the photoresist pattern as an etching mask.

17. The method of fabricating a nonvolatile memory device according to claim 16, wherein forming the third insulating layer further comprises:
performing a low pressure chemical vapor deposition (LPCVD) process using a gas mixture of dichlorosilane (DCS) and NH₃ to form a silicon nitride layer, the DCS and NH₃ being present at a mixing ratio from 0.65 to 1.0.

18. The method of fabricating a nonvolatile memory device according to claim 16, wherein forming the storage node layer further comprises:
performing a low pressure chemical vapor deposition (LPCVD) process using a gas mixture of DCS and NH₃ to form a silicon nitride layer, the DCS and NH₃ being present at a mixing ratio of 1.5 to 2.5.

19. The method of fabricating a nonvolatile memory device according to claim 17, wherein forming the storage node layer further comprises:
performing a low pressure chemical vapor deposition (LPCVD) process using a gas mixture of DCS and NH₃ to form a silicon nitride layer, the DCS and NH₃ being present at a mixing ratio of 1.5 to 2.5.

20. The method of fabricating a nonvolatile memory device according to claim 16, wherein forming the storage node layer and forming the third insulating layer further comprise:
performing a first low pressure chemical vapor deposition (LPCVD) process using a second gas mixture of having a first mixing ratio of dichlorosilane (DCS) and NH₃ to form the storage node layer from silicon nitride having a first trap density D_{T1}; and
performing a second low pressure chemical vapor deposition (LPCVD) process using a second gas mixture having a second mixing ratio of dichlorosilane (DCS) and NH₃ to form the third insulating layer of silicon nitride having a second trap density D_{T2}, wherein the first and second trap densities satisfy the expression D_{T1}>D_{T2}.
